(19) United States
(12) Patent Application Publication
(10) Pub. No.: US 2024/0417273 A1
(43) Pub. Date: Dec. 19, 2024

(54) PEROVSKITE OXIDE THIN FILM USING A SELECTIVE A-SITE ATOMIC GRADIENT AND METHOD OF PREPARATION THEREOF

(71) Applicant: POSTECH RESEARCH AND BUSINESS DEVELOPMENT FOUNDATION, Pohang-si (KR)

(72) Inventors: Daesu LEE, Pohang-si (KR); Sanghyeon KIM, Pohang-si (KR)

(21) Appl. No.: 18/679,584

(22) Filed: May 31, 2024

(30) Foreign Application Priority Data
Jun. 15, 2023 (KR) 10-2023- 0076849

(51) Int. Cl. C01G 23/00; C30B 23/06; C30B 29/32

(52) U.S. Cl. CPC C01G 23/006; C30B 23/06; C30B 29/32; C01P 2002/34; C01P 2002/50; C01P 2002/77; C01P 2002/78; C01P 2002/85; C01P 2004/04; C01P 2006/32; C01P 2006/40

(57) ABSTRACT

A perovskite oxide thin film comprising a compound represented by Chemical Formula 1, and has a layered perovskite structure, wherein a ratio of A′ atoms to all A-sites in one A-site (A+A′) atomic layer is different from that of three or more other A-site atomic layers in a thickness direction.

### CROSS-REFERENCE TO RELATED APPLICATION

This application claims priority to Korean Patent Application No. 10-2023-0076849 filed in the Korean Intellectual Property Office on Jun. 15, 2023, and all the benefits accruing therefrom under 35 U.S.C. § 119, the entire contents of which are incorporated herein by reference.

### BACKGROUND OF THE INVENTION

### (a) Field of the Invention

The present research has been conducted with support from the Samsung Research Funding & Incubation Center for Future Technology (Project Number: SRFC-MA2101-02).

The present research relates to a perovskite oxide thin film and its manufacturing method using selective A-site atomic gradients, and to a universal method that can generate large electric polarization and implement polar functionality in perovskite oxide ABO₃.

### (b) Description of the Related Art

Conventionally, the following methods are generally used to artificially break inversion symmetry or create polarization inside a material.

One example a method for controlling an oxygen octahedral rotation pattern. In this method, when a material with an oxygen octahedral rotation pattern (e.g., a⁻b⁺a⁻) without polar symmetry is grown in the form of a thin film on a substrate with a pattern with polar symmetry (e.g., a⁻a⁻a⁻), the material follows the same pattern as the substrate to achieve polar symmetry.

When a non-polar CaTiO₃ material with an oxygen octahedral rotation pattern of a⁻b⁺a⁻ in Glazer notation is grown on a LaAlO₃ with the a⁻a⁻a⁻ pattern, it shows polarity while having the same a⁻a⁻a⁻ pattern as the substrate.

Another example is a Schottky junction method. The Schottky junction method refers to a case of joining a metal material and a semiconductor material. This method implements polar properties through a built-in-field induced by band-bending occurring in a process for adjusting different Fermi levels. For example, if the built-in-field is generated by joining a semiconductor of niobium (Nb)-doped SrTiO₃ or TiO₂ with gold, piezoelectricity and pyroelectricity may occur.

In addition, still another example may be a flexoelectric effect. This method utilizes a phenomenon that electrical polarization occurs in all materials due to a strain gradient, that is, the flexoelectricity. While the piezoelectricity limitedly exists only in 20 crystal point groups, the flexoelectricity may occur advantageously in all 32 point groups. In addition, because the strain gradient is inversely proportional to a length unit, the flexoelectricity that more significantly acts at nano units and the electrical polarization that occurs through this may be variously used at the nanoscales.

Furthermore, yet another example may be a conventional compositional gradient method, which is a method of inducing a compositional gradient in a thickness direction through compositional ratio changes of two different constituent atoms and artificially breaking the inversion symmetry. This method has been conventionally used in metal alloys, etc. but recently used in some oxides. This method has an advantage of artificially/universally breaking the inversion symmetry through various material combinations.

However, the Schottky junction method or the oxygen octahedral rotation pattern control method respectively has limitations of working at junctions of metals and semiconductors and using only a substrate with a polar structure.

In addition, currently-known methods of utilizing the flexoelectric effect caused by a strain gradient have limitations of inevitably accompanying many crystallographic point defects and working only when used with other devices such as a scanning probe microscope.

In addition, the previously studied compositional gradient methods, have not yet been experimentally verified with respect to strong polarity (electrical polarization) and polar functionality artificially generatable therethrough and have limitations in a size of the polarity (electrical polarization) and functionality that can be implemented.

Accordingly, it is necessary to verify a method of universally inducing the strong polarity (electrical polarization) without being limited by a substrate, physical properties, or equipment, etc. and its functionality.

### PRIOR ART

### Non-Patent Reference

1. Kim, J. R., Jang, J., Go, KJ. et al. Stabilizing hidden room-temperature ferroelectricity via a metastable atomic distortion pattern. Nat Commun 11, 4944 2020.
2. Yang, M M., Luo, Z D., Mi, Z. et al. Piezoelectric and pyroelectric effects induced by interface polar symmetry. Nature 584, 377-381 2020
3. D. Lee, A. Yoon, S. Y. Jang, J.-G. Yoon, J.-S. Chung, M. Kim, J. F. Scott, T. W. Noh. Giant flexoelectric effect in ferroelectric epitaxial thin films. Phys. Rev. Lett. 107, 057602 2011
4. Wu, P C., Huang, R., Hsieh, Y H. et al. Electrical polarization induced by atomically engineered compositional gradient in complex oxide solid-solution. NPG Asia Mater 11, 17 2019
5. Damodaran, A., Pandya, S., Qi, Y. et al. Large polarization gradients and temperature-stable responses in compositionally-graded ferroelectrics. Nat Commun 8, 14961 2017

### SUMMARY OF THE INVENTION

One aspect of the present disclosure provides a perovskite oxide thin film that may universally generate inversion symmetry breaking inside a material without using a substrate having a special oxygen pattern or without help of other devices, may form polarization by flexoelectricity, and may achieve improved dielectric properties and pyroelectric effect.

A perovskite oxide thin film according to one aspect comprises a compound represented by Chemical Formula 1, and has a layered perovskite structure, wherein a ratio of A′ atoms to all A-sites in one A-site atomic layer is different from three or more other A-site atomic layers in the thickness direction.

A₁₋ₓA′ₓBO₃ [Chemical Formula 1]

In Chemical Formula 1, A and A′ are different divalent or trivalent cations, B is a tetravalent or trivalent cation, and 0≤x≤1.

A and A′ may each independently include strontium (Sr), calcium (Ca), barium (Ba), lanthanum (La), cerium (Ce), praseodymium (Pr), neodymium (Nd), promerium (Pm), samarium (Sm), europium (Eu), gadolinium (Gd), terbium (Tb), dysprosium (Dy), holmium (Ho), erbium (Er), thulium (Tm), ytterbium (Yb), lutepium (Lu), or a combination thereof.

B may include titanium (Ti), vanadium (V), chromium (Cr), manganese (Mn), iron (Fe), cobalt (Co), nickel (Ni), copper (Cu), zinc (Zn), or a combination thereof.

One A-site atomic layer may be an A-site atomic layer (first atomic layer) located inside in a thickness direction of the perovskite oxide thin film.

Three or more different A-site atomic layers may be, respectively, an A-site atomic layer (second atomic layer) that is located on one surface of the perovskite oxide thin film, an A-site atomic layer (third atomic layer) that is located on the other surface of the perovskite oxide thin film, and an A-site atomic layer (fourth atomic layer) that is located inside in the thickness direction of the perovskite oxide thin film and is different from the first atomic layer.

Ratios (R¹) of A′ atoms to all A-sites in the first atomic layer and the fourth atomic layer may each independently be greater than 0 and less than about 1.

A ratio (R²) of A′ atoms to all A-sites in the second atomic layer may be greater than 0 and less than about 1.

A ratio (R³) of A′ atoms to all A-sites in the third atomic layer may be greater than about 0 and less than or equal to about 1.

The first atomic layer may be an A-site atomic layer of the compound represented by Chemical Formula 1.

The second atomic layer may be an A-site atomic layer of a compound represented by Chemical Formula 2.

ABO₃ [Chemical Formula 2]

In Chemical Formula 2, A is a divalent or trivalent cation different from A′, and B is a tetravalent or trivalent cation.

The third atomic layer may be an A-site atomic layer of the compound represented by Chemical Formula 3.

A′BO₃ [Chemical Formula 3]

In Chemical Formula 3, A′ is a divalent or trivalent cation different from A, and B is a tetravalent or trivalent cation.

The fourth atomic layer may be an A-site atomic layer of the compound represented by Chemical Formula 4.

A_{1-z}A′_{z}BO₃ [Chemical Formula 4]

In Chemical Formula 4, A and A′ are different divalent or trivalent cations, B is a tetravalent or trivalent cation, 0<z<1, and z≠x.

The compound represented by Chemical Formula 1 may be Ba₁₋ₓCaₓTiO₃, the compound represented by Chemical Formula 2 may be BaTiO₃, the compound represented by Chemical Formula 3 may be CaTiO₃, and the compound represented by Chemical Formula 4 may be Ba_{1-z}Ca_{z}TiO₃.

The perovskite oxide thin film may have a thickness direction gradient in which the ratio of A′ atoms to all A-sites in one A-site atomic layer changes in the thickness direction.

The perovskite oxide thin film may have a thickness gradient of 0.5% to 50%, calculated by Equation 1.

$$Δ G ( \% ) = ( {AL}_{n + 1} - A {L}_{n} ) \times 100 \qquad [ Equation 1 ]$$

In Equation 1, ΔG is a gradient in the thickness direction, ALₙ is a ratio of A′ atoms to all A-sites in any one A-site atomic layer, and ALₙ₊₁ is a ratio of A′ atoms to all A-sites in other A-site atomic layers separated by less than or equal to about 0.4 nm.

A total thickness of the perovskite oxide thin film may be about 1.2 nm to about 100 nm.

An atomic ratio of A atoms to A′ atoms in the entire perovskite oxide thin film may be about 30:70 to about 70:30.

An average magnitude of polarization induced throughout the perovskite oxide thin film may be greater than or equal to about 20 uC/cm².

A dielectric loss throughout the perovskite oxide thin film may be less than or equal to about 0.1 under measurement conditions of a frequency of 1 kHz to 2 MHz and an AC level of 10 mV to 200 mV.

A pyroelectric coefficient of the entire perovskite oxide thin film may be greater than or equal to about 10⁶ uC/m²K under measurement conditions of a sinusoidal temperature change period of 20 seconds to 120 seconds and low frequency period (LFP) with a temperature change of 0.5 K to 8 K.

According to another aspect, a method of preparing a perovskite oxide thin film that comprises a compound represented by Chemical Formula 1 and has a layered perovskite structure, on a substrate wherein a ratio of A′ atoms to all A-sites in one A-site (A+A′) atomic layer is different from that of three or more other A-site atomic layers in a thickness direction.

A₁₋ₓA′ₓBO₃ [Chemical Formula 1]

In Chemical Formula 1, A and A′ are different divalent or trivalent cations, B is a tetravalent or trivalent cation, and 0≤x≤1.

The perovskite oxide thin film may be formed by a physical vapor deposition (PVD) method, a chemical vapor deposition (CVD) method, a molecular beam epitaxy (MBE) method, an atomic layer deposition (ALD) method, a pulsed laser deposition (PLD) method, or a sputter method.

The perovskite oxide thin film may be formed using PLD (Pulsed laser deposition) equipment equipped with a high-pressure-high-speed reflection electron diffraction device (reflection high energy electron diffraction), under certain conditions of a rate of 200 pulses/unit cell to 2 pulses/unit cell.

According to embodiments, the perovskite oxide thin film can universally generate inversion symmetry breaking inside the material and form polarization by flexoelectricity without using a substrate with a special oxygen pattern or without help of other devices, has improved dielectric properties, and can generate a pyroelectric effect.

### BRIEF DESCRIPTION OF THE DRAWINGS

FIG. 1 is a schematic representation of a perovskite oxide thin film according to an embodiment.

FIG. 2 shows RHEED intensity oscillations for forming an A-site atomic layer gradient when preparing a perovskite oxide thin film having an A-site atomic layer gradient using high-pressure-high-speed reflection electron diffraction device (reflection high energy electron diffraction, RHEED).

FIG. 3 shows aberration-corrected scanning transmission electron microscope (STEM) measurement results of the solid-solution Ba_{0.5}Ca_{0.5}TiO₃ thin film prepared in Comparative Example.

FIG. 4 shows aberration-corrected scanning transmission electron microscope (STEM) measurement results of the (Ba, Ca)TiO₃ thin film having an A-site atomic layer gradient prepared in Example.

FIG. 5 shows results of atomic-scale chemical mapping using energy dispersive X-ray spectroscopy (EDS) of the solid-solution Ba_{0.5}Ca_{0.5}TiO₃ thin film prepared in Comparative Example.

FIG. 6 shows results of atomic-scale chemical mapping using energy dispersive X-ray spectroscopy (EDS) of the (Ba, Ca)TiO₃ thin film with A-site atomic layer gradient prepared in Example.

FIGS. 7 and 8 show polarization maps corresponding to FIG. 5 (Comparative Example) and FIG. 6 (Example), respectively.

FIG. 9 is a graph showing the frequency-dependent dielectric constant of the solid-solution Ba_{0.5}Ca_{0.5}TiO₃ thin film prepared in Comparative Example and the (Ba, Ca)TiO₃ thin film having an A-site atomic layer gradient prepared in Example.

FIG. 10 is a graph showing the tan 6 characteristics of the solid-solution Ba_{0.5}Ca_{0.5}TiO₃ thin film prepared in Comparative Example and the (Ba, Ca)TiO₃ thin film having an A-site atomic layer gradient prepared in Example.

FIG. 11 a graph showing pyroelectric characteristics of a (Ba,Ca)TiO₃ thin film having an A-site atomic layer gradient prepared in Example, a (Ca,Ba)TiO₃ thin film with an atomic layer gradient in the opposite direction, and a solid-solution Ba_{0.5}Ca_{0.5}TiO₃ thin film.

### DETAILED DESCRIPTION OF THE EMBODIMENTS

Hereinafter, with reference to the attached drawings, various embodiments of the present invention will be described in detail so that those skilled in the art can easily implement the present invention. The invention may be implemented in many different forms and is not limited to the embodiments described herein. In order to clearly explain the present invention, parts that are not relevant to the description are omitted, and identical or similar components are assigned the same reference numerals throughout the specification.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

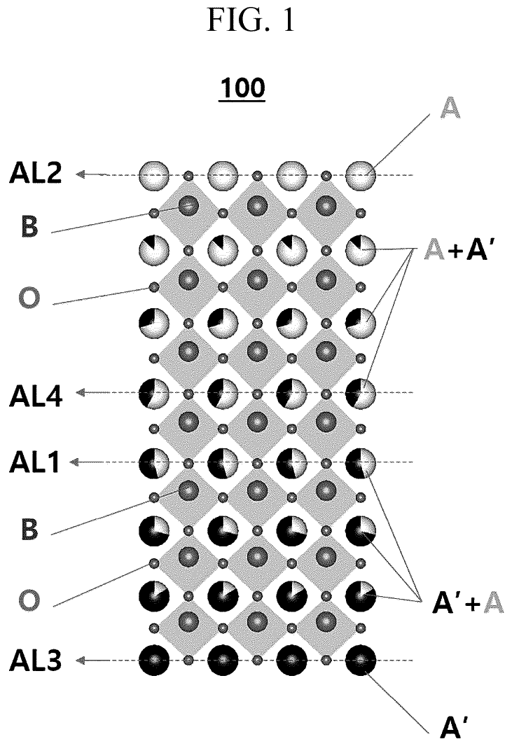

A perovskite oxide thin film 100 according to an embodiment will be described with reference to FIG. 1. FIG. 1 is a view schematically showing a perovskite oxide thin film 100 according to an embodiment.

Referring to FIG. 1, the perovskite oxide thin film 100 according to an embodiment comprises a compound represented by Chemical Formula 1.

A₁₋ₓA′ₓBO₃ [Chemical Formula 1]

In Chemical Formula 1, A and A′ are different divalent or trivalent cations, B is a tetravalent or trivalent cation, and 0≤x≤1. At this time, B may be a cation different from A and A′.

For example, in Chemical Formula 1, A and A′ may each independently include an alkaline earth metal such as strontium (Sr), calcium (Ca), or barium (Ba); a rare earth metal such as lanthanum (La), cerium (Ce), praseodymium (Pr), neodymium (Nd), promerium (Pm), samarium (Sm), europium (Eu), gadolinium (Gd), terbium (Tb), dysprosium (Dy), holmium (Ho), erbium (Er), thulium (Tm), ytterbium (Yb), or lutepium (Lu); or a combination thereof. Herein, A and A′ may be different from each other, and for example, A may be barium (Ba) and A′ may be calcium (Ca).

B may be a transition metal including titanium (Ti), vanadium (V), chromium (Cr), manganese (Mn), iron (Fe), cobalt (Co), nickel (Ni), copper (Cu), zinc (Zn), or a combination thereof.

x represents the atomic percent of A′ atoms and may be 0≤x≤1.

The perovskite oxide thin film 100 has a layered perovskite structure.

For example, in the layered perovskite structure, A atoms or A′ atoms are located between BO₆ octahedrons that share each edge in three dimensions. For reference, FIG. 1 shows the two-dimensional structure of layered perovskite, and the BO₆ octahedrons are shown as squares.

The layered perovskite structure includes a plurality of A-site atomic layers including A atoms, A′ atoms, or both between BO₆ octahedrons in the thickness direction. Additionally, A-site atomic layers may include additional oxygen atoms because they share oxygen atoms with BO₆ octahedrons.

Herein, the ratio of A′ atoms to all A-sites in one A-site atomic layer may be different from three or more other A-site atomic layers in the thickness direction. Herein, the thickness direction may be a direction perpendicular to the substrate (not shown) or a direction parallel to the growth direction of the perovskite oxide thin film 100. The perovskite oxide thin film may be a thin film grown in the 001 plane direction, a thin film grown in the 110 plane direction, or a thin film grown in the 111 plane direction. Hereinafter, the thin film grown in the 001 plane direction will be mainly described, but is not limited thereto.

As an example, one A-site atomic layer may be an A-site atomic layer (hereinafter referred to as “first atomic layer AL1”) located inside in the thickness direction of the perovskite oxide thin film 100. Three or more other A-site atomic layers may include, respectively, an A-site atomic layer (hereinafter referred to as “second atomic layer AL2”) located on one surface of the perovskite oxide thin film 100, an A-site atomic layer (hereinafter referred to as “third atomic layer AL3”) located on the other surface of the perovskite oxide thin film 100, and an A-site atomic layer (hereinafter referred to as “fourth atomic layer AL4”) located inside in the thickness direction of the perovskite oxide thin film 100 and being different from the first atomic layer.

That is, the second atomic layer AL2 and the third atomic layer AL3 may be located on one surface and the other surface in the thickness direction of the perovskite oxide thin film 100, respectively, and the first atomic layer AL1 and the fourth atomic layer AL4 may be located between the second atomic layer AL2 and the third atomic layer AL3.

For example, the first atomic layer AL1 may be an A-site atomic layer of the compound represented by Chemical Formula 1. Herein, the ratio (R¹) of A′ atoms to the all A-sites in the first atomic layer AL1 may be greater than about 0 and less than about 1, for example greater than or equal to about 0.14 and less than about 1, greater than or equal to about 0.28 and less than about 1, greater than or equal to about 0.58 and less than about 1, greater than or equal to about 0.72 and less than about 1, or greater than or equal to about 0.86 and less than about 1, greater than about 0 and less than or equal to about 0.14, greater than about 0 and less than or equal to about 0.28, greater than about 0 and less than or equal to about 0.58, greater than about 0 and less than or equal to about 0.72, or greater than about 0 and less than or equal to about 0.86. As an example, the compound represented by Chemical Formula 1 included in the first atomic layer AL1 may be Ba₁₋ₓCaₓTiO₃.

In the second atomic layer AL2, a ratio (R²) of A′ atoms to all A-sites may be greater than or equal to about 0 and less than about 1, for example, greater than or equal to about 0.14 and less than about 1, greater than or equal to about 0.28 and less than about 1, or greater than or equal to about 0.58 and less than about 1, greater than or equal to about 0.72 and less than about 1, or greater than or equal to about 0.86 and less than about 1.

The second atomic layer AL2 may be an A-site atomic layer of a compound represented by Chemical Formula 2.

ABO₃ [Chemical Formula 2]

In Chemical Formula 2, A is a divalent or trivalent cation different from A′, and B is a tetravalent or trivalent cation. For example, the compound represented by Chemical Formula 2 may be BaTiO₃.

In the third atomic layer AL3, a ratio (R²) of A′ atoms to all A-sites may be greater than about 0 and less than or equal to about 1, for example, greater than about 0 and less than or equal to about 0.14, greater than about 0 and less than or equal to about 0.28, greater than about 0 and less than or equal to about 0.58, greater than about 0 and less than or equal to about 0.72, or greater than about 0 and less than or equal to about 0.86.

The third atomic layer AL3 may be an A-site atomic layer of a compound represented by Chemical Formula 3.

A′BO₃ [Chemical Formula 3]

In Chemical Formula 3, A′ is a divalent or trivalent cation different from A, and B is a tetravalent or trivalent cation. For example, the compound represented by Chemical Formula 3 may be CaTiO₃.

The fourth atomic layer AL4 may be an A-site atomic layer of the compound represented by Chemical Formula 4.

A_{1-z}A′_{z}BO₃ [Chemical Formula 4]

In Chemical Formula 4, A and A′ are different divalent or trivalent cations, B is a tetravalent or trivalent cation, 0<z<1, and z≠x.

Herein, in the fourth atomic layer AL4, a ratio (R¹) of A′ atoms to all A-sites may be greater than about 0 and less than about 1, for example greater than or equal to about 0.14 and less than about 1, greater than or equal to about 0.28 and less than about 1, greater than or equal to about 0.58 and less than about 1, greater than or equal to about 0.72 and less than about 1, or greater than or equal to about 0.86 and less than about 1, greater than about 0 and less than or equal to about 0.14, greater than about 0 and less than or equal to about 0.28, greater than about 0 and less than or equal to about 0.58, greater than about 0 and less than or equal to about 0.72, or greater than about 0 and less than or equal to about 0.86. As an example, the compound represented by Chemical Formula 4 included in the fourth atomic layer AL4 may be Ba_{1-z}Ca_{z}TiO₃, where z is different from x in Chemical Formula 1.

In this way, the ratio of A′ atoms to all A-sites in the first atomic layer AL1 is different from the ratio of three or more other second atomic layer AL2, third atomic layer AL3, and fourth atomic layer AL4 in the thickness direction.

Additionally, the first atomic layer AL1 and the fourth atomic layer AL4 may be the closest A-site atomic layers adjacent to each other. That is, the perovskite oxide thin film 100 may have a different ratio of A′ atoms to all A-sites in units of A-site atomic layers.

As an example, the perovskite oxide thin film 100 may have a thickness direction gradient in which the ratio of A′ atoms to all A-sites in one A-site atomic layer changes in the thickness direction.

For example, the ratio of A′ atoms to all A-sites of the first atomic layer AL1 may stepwise or gradually decrease as it approaches the second atomic layer AL2, and the ratio of A′ atoms to all A-sites may increase stepwise or gradually as it approaches the third atomic layer AL3.

That is, the thickness direction gradient calculated by Equation 1 may be about 0.5% to about 50%, or about 2% to about 20%.

$$Δ G ( \% ) = ( {AL}_{n + 1} - A {L}_{n} ) \times 100 \qquad [ Equation 1 ]$$

In Equation 1, ΔG is a gradient in the thickness direction, ALₙ is a ratio of A′ atoms to all A-sites in any one A-site atomic layer, and ALₙ₊₁ is a ratio of A′ atoms to all A-sites in other A-site atomic layers separated by less than or equal to about 0.4 nm. For example, ALₙ may be the ratio of A′ atoms to all A-sites in the first atomic layer AL1, and ALₙ₊₁ may be the ratio of A′ atoms to all A-sites in the fourth atomic layer AL4.

As an example, FIG. 1 shows a case where 7-layer perovskite crystal structures are stacked. Accordingly, it includes 8 layers of A-site atomic layers, and the ratio of A′ atoms to all A-sites in each A-site atomic layer has a gradient in the thickness direction in which the ratio of A′ atoms changes stepwise or gradually in the thickness direction. For reference, in FIG. 1, the difference in the ratio of A′ atoms to all A-sites is indicated by shaded ratios within the atoms.

For example, in the second atomic layer AL2, the shading of the A′ atoms is 0%, indicating that the atomic ratio (A:A′) of A atoms to A′ atoms is 1.00:0.00, in the third atomic layer AL3, the shading of the A′ atom is 100%, indicating that the atomic ratio (A:A′) of the A atoms and A′ atoms is 0.00:1.0, in the first atomic layer AL1, the shading of A′ atoms is 58%, indicating that the atomic ratio (A:A′) of A atoms to A′ atoms is 0.42:0.58, and in the fourth atomic layer AL4, the shading of A′ atoms is 42%, indicating that the atomic ratio of (A:A′) of A atoms to A′ atoms is 0.58:0.42.

In this way, the perovskite oxide thin film 100 selectively and precisely controls the ratio of A atoms and A′ atoms having different ionic radius sizes for each A-site atomic layer, resulting in a very large strain gradient in the nano-thickness unit.

Therefore, it is possible to universally break the inversion symmetry inside the material and form polarization by flexoelectricity without using a substrate with a special oxygen pattern or without the help of other devices. For example, when making an atomic gradient thin film with a thickness of about 3 nm using Ba²⁺ ions with an ionic radius of 0.161 nm and Ca²⁺ ions with an ionic radius of 0.131 nm at the A position in the titanate thin film of ATiO₃, the lattice gradient is approximately 10⁸/m, and considering that the general flexoelectric coefficient is 10⁻⁹ C/m to 10⁻⁸ C/m, a large polarization of about 10 uC/cm² to about 100 uC/cm² can be generated. This method is universally applicable regardless of the ion at the B position that determines the physical properties, and thus it can be used to combine various physical properties and polar structures.

As an example, a total thickness of the perovskite oxide thin film 100 may be about 1.2 nm to about 100 nm, for example, about 2.4 nm to about 20 nm, or about 4.3 nm to about 10 nm. That is, as the ratio of A′ atoms to all A-sites in the A-site atomic layer changes in units of A-site atomic layers, the perovskite oxide thin film 100 according to an embodiment can induce strong and stable electrical polarization even in ultra-thin films of about 4 nm.

The atomic ratio of A atoms to A′ atoms in the entire perovskite oxide thin film 100 may be about 30:70 to about 70:30, for example, about 40:60 to about 60:40, or about 50:50. For example, CaTiO₃ is a non-polar material without polarization, and BaTiO₃ has less than or equal to about 20 uC/cm² at a thin film thickness. In the case of a (Ba_{0.5}Ca_{0.5})TiO₃ solid-solution thin film in which CaTiO₃ and BaTiO₃ are evenly mixed, with a Ba:Ca ratio of 50:50, there is no polarization. On the other hand, in the case of the perovskite oxide thin film 100 according to an embodiment, as the ratio of A′ atoms to all A-sites in the A-site atomic layer changes in units of A-site atomic layers, even when the atomic ratio of A atoms to A′ atoms in the entire perovskite oxide thin film 100 is 50:50, flexoelectricity can be exhibited.

Accordingly, an average magnitude of the polarization induced throughout the perovskite oxide thin film 100 may be greater than or equal to about 20 uC/cm², for example, greater than or equal to about 30 uC/cm², or greater than or equal to about 50 uC/cm², and a maximum magnitude of polarization induced throughout the perovskite oxide thin film 100 may be greater than or equal to about 60 uC/cm², greater than or equal to about 70 uC/cm², or greater than or equal to about 100 uC/cm².

Because polarization is formed during thin film synthesis at high temperature, as the perovskite oxide thin film 100 according to an embodiment is a thin film at high temperature as the ratio of A′ atoms to all A-sites in the A-site atomic layer changes in units of A-site atomic layers, charged defects (for example, oxygen vacancies) move toward the interface, leading to a very clean, defect-free state inside the thin film. In addition, because the perovskite oxide thin film 100 has a large polarization gradient, a bulk bound charge density (ρ_{b}=−∇·P) with a large negative value is induced, and therefore, electrons, which are major extrinsic carriers in oxides, are depleted inside the thin film. As a result, the perovskite oxide thin film 100 has improved dielectric properties even as a very thin and ultra-thin film.

Accordingly, the dielectric loss in the entire perovskite oxide thin film 100 is less than or equal to about 0.1, for example, less than or equal to about 0.01, or less than or equal to about 0.001 under measurement conditions of a frequency of 1 kHz to 2 MHz and an AC level of 10 mV to 200 mV. On the other hand, in thin films with a thickness of approximately 5 nm manufactured using conventional methods, leakage current is very large due to trap charges, making it impossible to measure dielectric and functionality-related results.

In addition, since the perovskite oxide thin film 100 according to an embodiment inevitably has a region inside the thin film where a paraelectric-ferroelectric phase transition occurs within the temperature range for measuring pyroelectricity, within the measurement temperature range, the dielectric constant, the flexoelectric coupling coefficient, and the flexoelectric coefficient proportional to the product of these two values may change rapidly, and the changes in flexoelectric coefficient in response to temperature changes may diverge. As a result, the perovskite oxide thin film 100 has ultra-large pyroelectric properties even as a very thin and ultra-thin film.

Accordingly, the pyroelectric coefficient of the entire perovskite oxide thin film 100 may be greater than or equal to about 10⁵ uC/m²K, for example greater than or equal to about 10⁶ uC/m²K, or greater than or equal to about 10⁷ uC/m²K under measurement conditions of low frequency cycle (LFP) with a sinusoidal temperature change period of 20 seconds to 120 seconds and a temperature change of 0.5 K to 8 K. On the other hand, in thin films with a thickness of about 5 nm manufactured by conventional methods, trap charges generate currents that are out of phase with the pyroelectric current, making it impossible to measure pyroelectricity and functionality-related results.

The perovskite oxide thin film 100 according to an embodiment may be formed by a physical vapor deposition (PVD) method, a chemical vapor deposition (CVD) method, a molecular beam epitaxy (MBE) method, an atomic layer deposition (ALD) method, a pulsed laser deposition (PLD) method, or a sputter method.

As an example, the perovskite oxide thin film 100 may be formed by using a pulsed laser deposition (PLD) equipment equipped with a high pressure-high energy reflection electron diffraction device, under conditions of 200 pulses/unit cell to 2 pulses/unit cell, or under conditions of 50 pulses/unit cell or more.

When using PLD (Pulsed laser deposition) equipment equipped with high-pressure-high energy electron diffraction, by using only the first target including A atoms and the second target including A′ atoms, materials with dozens of different composition ratios of A atoms:A′ atoms can be controlled at the single atomic layer level. That is, there is no need to use N targets to manufacture N-layer thin films as in the prior art.

Hereinafter, specific examples of the invention are presented. However, the examples described below are only for illustrating or explaining the invention in detail, and should not limit the scope of the invention.

### Preparation Example: Preparation of Perovskite Oxide Thin Film

### Example

A (Ba,Ca)TiO₃ epitaxy thin film with A-site atomic layer gradients were grown on a commercially available SrTiO₃(001) monocrystalline substrate in a pulse laser deposition (PLD) method.

The SrTiO₃ substrate was prepared by soaking in deionized water for 1 hour and etching with buffered hydrofluoric acid for 30 seconds.

Subsequently, the substrate was annealed in oxygen at 1000° C. for 6 hours to fabricate an atomically smooth single TiO₂ surface with unit cell steps.

Then, each SrRuO₃ layer with a thickness of 20 nm and 5 nm was deposited respectively as lower and upper electrodes.

Herein, the SrRuO₃ thin film was deposited by using a KrF excimer laser (λ=248 nm) with energy density of 1.5 J/cm² or less at a repetition rate of 3 Hz.

During the growth process, a temperature and an oxygen partial pressure were respectively maintained at 675° C. and 100 mTorr.

In the PLD system, a high-pressure reflection high-energy electron diffraction (RHEED) was mounted to continuously monitor a growth rate.

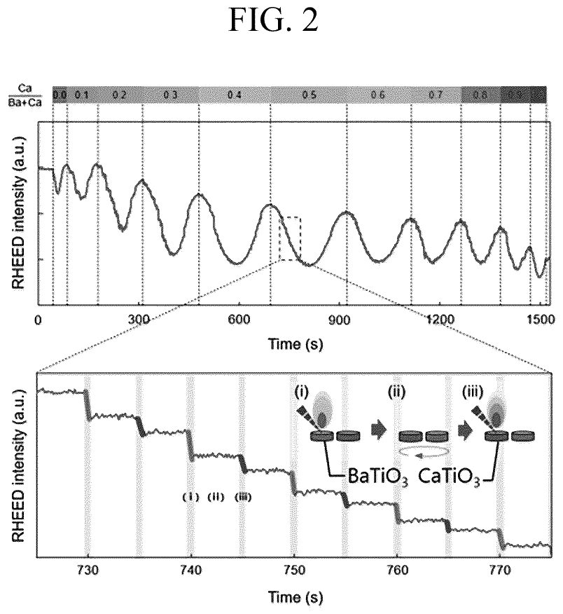

Based on RHEED vibration data of each BaTiO₃ and CaTiO₃ film growth on the 20 nm-thick SrRuO₃ lower electrode, the (Ba,Ca)TiO₃ thin film with A-site atomic layer gradients was controlled to have a deposition rate of 0.2 uc/pulse or less (FIG. 2).

The (Ba,Ca)TiO₃ thin film with A-site atomic layer gradients was grown at a temperature of 600° C. with laser energy density of 1.0 J/cm² or less at an oxygen pressure of 10 mtorr at a repetition speed of 1 Hz.

### Comparative Example

BaTiO₃, a solid-solution Ba_{0.5}Ca_{0.5}TiO₃ thin film, and a superlattice BaTiO₃/CaTiO₃ alternately grown with a thickness of 1 uc were prepared under the same conditions as in the example.

After the growth process, the obtained film was slowly cooled to room temperature at 100 Torr of oxygen.

In order to measure dielectric properties according to frequency, a 60 nm-thick Pt layer was deposited on top of the SrRuO₃ layer through electron beam deposition.

The upper Pt of the SrRuO₃ electrode was patterned by electron beam lithography and ion-milling and had a dimension of a diameter of 15 μm and a thickness of 70 nm or less for the measurement.

In order to measure pyroelectric characteristics according to sinusoidal temperature changes, after depositing a 20 nm-thick SrRuO₃ lower electrode, a (Ba,Ca)TiO₃ thin film with A-site atomic layer gradients, a (Ca,Ba)TiO₃ thin film with atomic layer gradients in an opposite direction thereto, and a solid-solution Ba_{0.5}Ca_{0.5}TiO₃ thin film, a Pt electrode with a thickness of 60 nm and a diameter of 50 μm was formed in a lift-off method.

### Experimental Example 1: Polarization Characteristics of Perovskite Oxide Thin Film

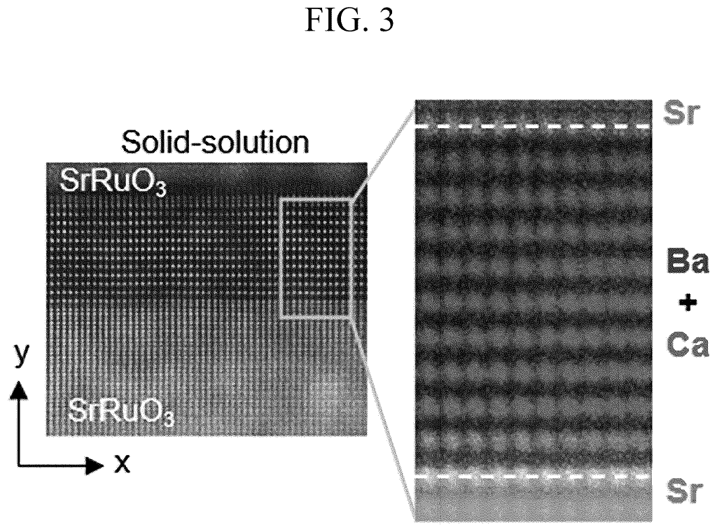

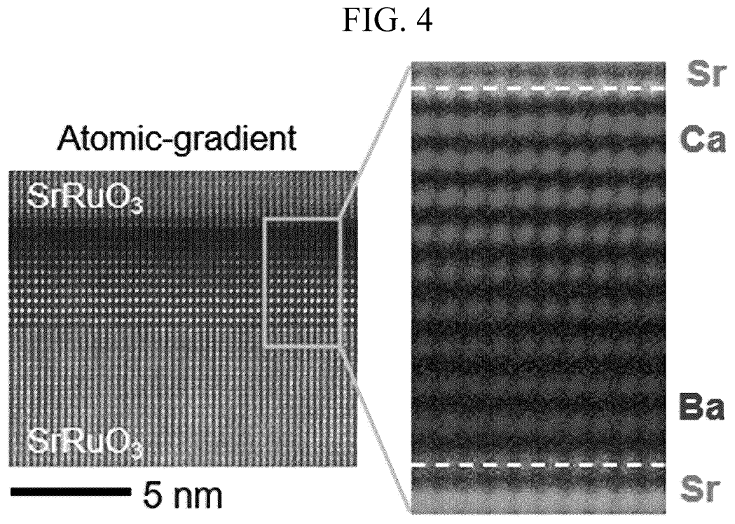

FIG. 3 shows aberration-corrected scanning transmission electron microscope (STEM) measurement results of the solid-solution Ba_{0.5}Ca_{0.5}TiO₃ thin film prepared in the comparative example, and FIG. 4 shows aberration-corrected scanning transmission electron microscope (STEM) measurement results of the (Ba,Ca)TiO₃ thin film with A-site atomic layer gradients prepared in the example.

Referring to FIGS. 3 and 4, high quality of the thin film and the atomic ratio gradients of the A-site atomic layer through gradual contrast changes were confirmed, and compared with a solid-solution Ba_{0.5}Ca_{0.5}TiO₃ thin film having uniform Ba and Ca atoms throughout the thin film, the (Ba,Ca)TiO₃ thin film with A-site atomic layer gradients exhibited gradual changes in Ba and Ca atom amounts.

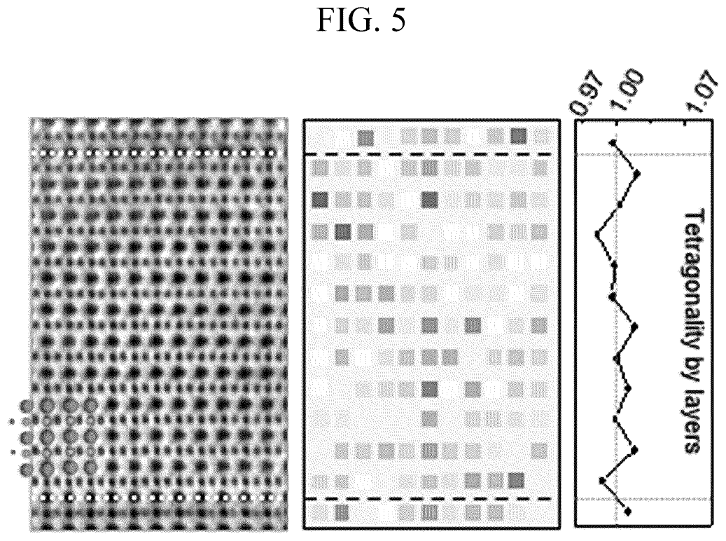

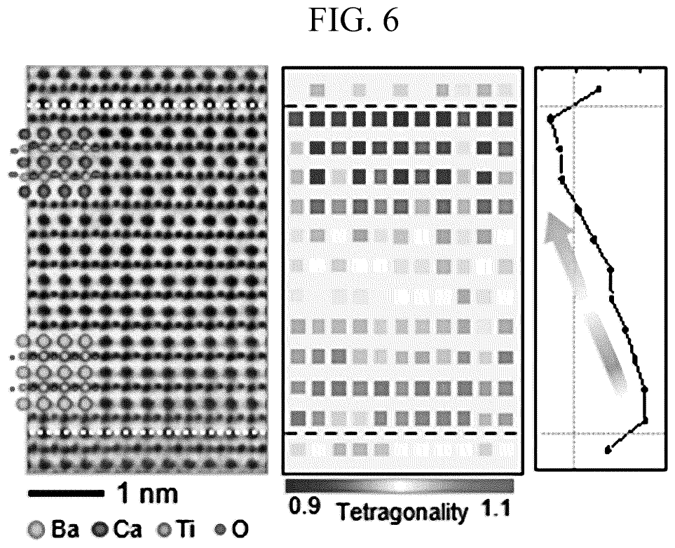

FIG. 5 shows the results of atomic-scale chemical mapping using energy dispersive X-ray spectroscopy (EDS) of the solid-solution Ba_{0.5}Ca_{0.5}TiO₃ thin film prepared in the comparative example, and FIG. 6 shows the results of atomic-scale chemical mapping using energy dispersive X-ray spectroscopy (EDS) of the (Ba,Ca)TiO₃ thin film with A-site atomic layer gradients prepared in the example.

Referring to FIGS. 5 and 6, the solid-solution Ba_{0.5}Ca_{0.5}TiO₃ thin film exhibited uniform lattice without significant deviation, but the (Ba,Ca)TiO₃ thin film with A-site atomic layer gradients exhibited a clear gradient in a lattice strain, wherein an out-of-plane lattice parameter decreased from BaTiO₃ to CaTiO₃ along the chemical gradient.

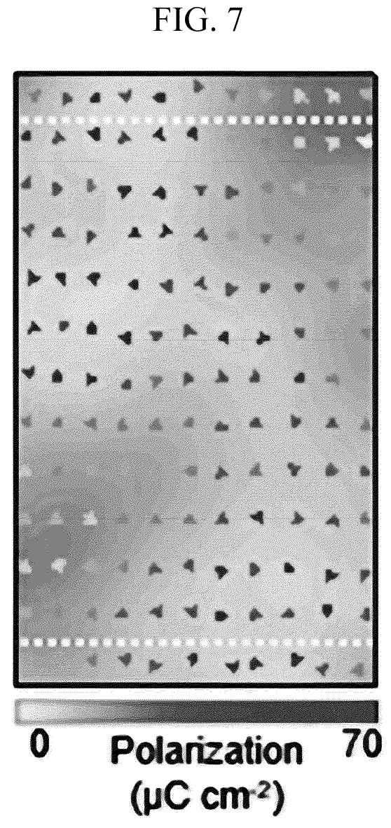

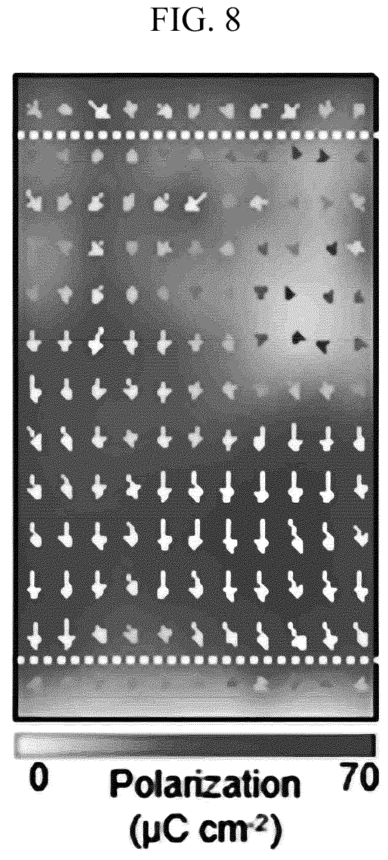

FIGS. 7 and 8 show polarization maps corresponding to FIGS. 5 and 6, respectively.

Referring to FIGS. 7 and 8, the solid-solution Ba_{0.5}Ca_{0.5}TiO₃ thin film exhibited no clear polarization, but the (Ba, Ca)TiO₃ thin film with A-site atomic layer gradients generated a large downward polarization of 28.4 μC cm² on average, which locally reached 60 μC cm² near the bottom BaTiO₃ layer.

### Experimental Example 2: Dielectric Properties of Perovskite Oxide Thin Film

In order to measure dielectric properties of the (Ba,Ca)TiO₃ thin film with A-site atomic layer gradients, a metal-insulator-metal structure was prepared. This structure consisted of a 60 nm-thick Pt layer and a 5 nm-thick SrRuO₃ layer as an upper electrode.

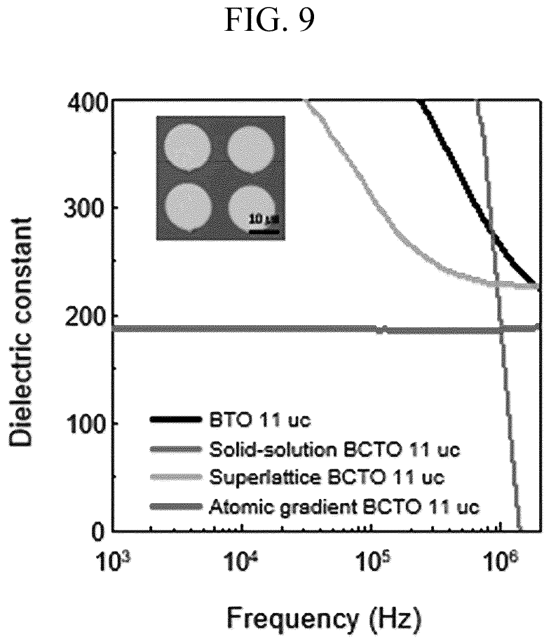

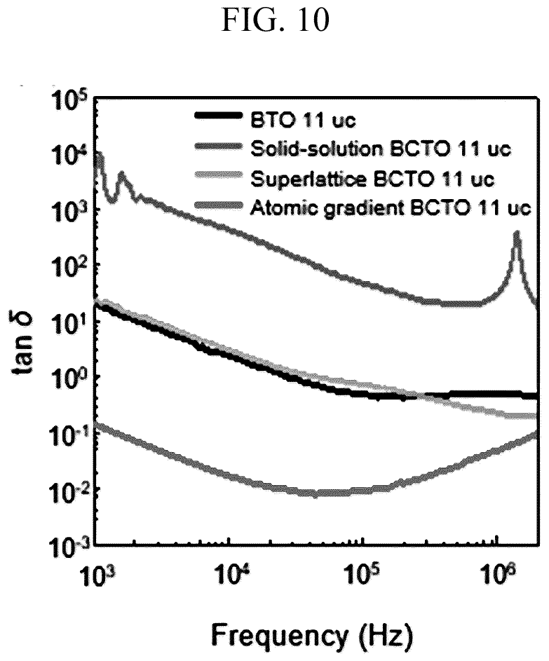

FIG. 9 is a graph showing the frequency-dependent dielectric constant of the (Ba,Ca)TiO₃ thin film with A-site atomic layer gradients prepared in the example, and FIG. 10 is a graph showing the tan 6 characteristics of the (Ba,Ca)TiO₃ thin film with A-site atomic layer gradients prepared in Example.

For comparison, BaTiO₃ (BTO), solid-solution Ba_{0.5}Ca_{0.5}TiO₃ (BCTO), and superlattice BaTiO₃/CaTiO₃ (BCTO) with the same thickness of 11 uc were prepared.

Referring to FIGS. 9 and 10, the (Ba,Ca)TiO₃ thin film with A-site atomic layer gradients (atomic gradient BCTO) exhibited a stable dielectric constant and low tan 6 within a frequency range of 1 kHz to 2 MHz. Herein, the tan 6 decreased and then, increased according to the frequencies, which indicates that conduction and an interfacial polarization loss occurred at low frequencies, but at high frequencies, a relaxation polarization loss occurred.

### Experimental Example 3: Pyroelectric Characteristics of Perovskite Oxide Thin Film

In order to measure pyroelectric characteristics of the (Ba,Ca)TiO₃ thin film with A-site atomic layer gradients, a metal-insulator-metal structure was prepared. As an upper electrode, Pt with a thickness of 60 nm and a diameter 50 μm was formed in a lift-off method right respectively on the (Ba,Ca)TiO₃ thin film with A-site atomic layer gradients (atomic gradient BCTO), a (Ca,Ba)TiO₃ thin film with A-site atomic layer gradients (atomic gradient CBTO), and a solid-solution Ba_{0.5}Ca_{0.5}TiO₃ thin film.

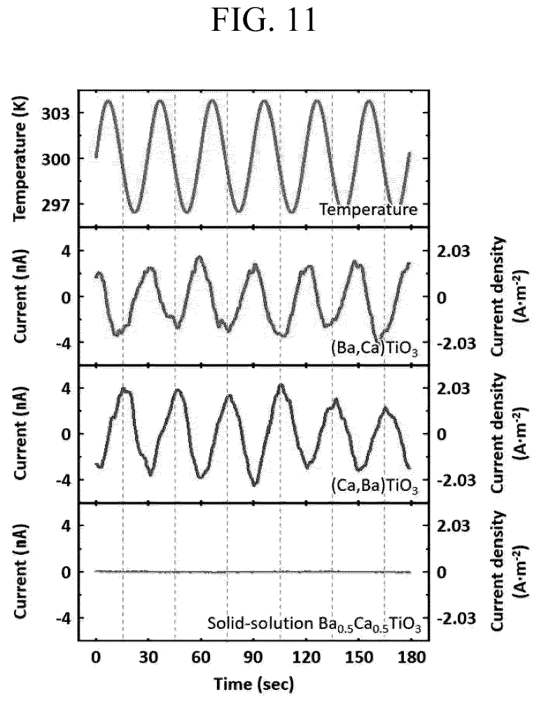

FIG. 11 a graph showing pyroelectric currents depending on sinusoidal temperature changes of the (Ba,Ca)TiO₃ thin film having an A-site atomic layer gradient, the (Ca,Ba)TiO₃ thin film with A-site atomic layer gradients, and the solid-solution Ba_{0.5}Ca_{0.5}TiO₃ thin film prepared in the example.

Referring to FIG. 11, the (Ba,Ca)TiO₃ thin film with A-site atomic layer gradients and the (Ca,Ba)TiO₃ thin film with A-site atomic layer gradients generated pyroelectric currents proportional to temperature changes over time (dT/dt) under conditions of a sinusoidal 30-second temperature change period and a temperature change size of 7.5 K. Herein, the pyroelectric currents of the (Ba,Ca)TiO₃ thin film with A-site atomic layer gradients and the (Ca,Ba)TiO₃ thin film with A-site atomic layer gradients exhibited phases proportional to the temperature change over time (dT/dt) but in an opposite direction each other, which indicates that because the films had polarization in the opposite direction each other, charges measured in the upper electrodes had opposite polarity. In contrast, the solid-solution Ba_{0.5}Ca_{0.5}TiO₃ thin film exhibited directly proportional results to temperature changes, which was confirmed to be non-pyroelectric currents generated by defects such as space charges or oxygen vacancy rather than pyroelectric currents by polarization.

In conclusion, in the present example embodiment, the A-site atomic layer gradient thin film was successfully designed by controlling A site atoms in an ATiO₃ perovskite structure.

The (Ba,Ca)TiO₃ thin film with A-site atomic layer gradients exhibited that the atom gradients induced a strain gradient of 20×10⁶/m in an 11 uc-thick film without structural defects.

As a result, a flexo electric field generate a large local electrical polarization of 60 μC cm⁻² in the (Ba,Ca)TiO₃ thin film with A-site atomic layer gradients.

The (Ba, Ca)TiO₃ thin film with A-site atomic layer gradients had a dielectric constant of about 220 with a low loss (e.g., tan 6 of less than 0.1) within a frequency range of 1 kHz to 2 MHz, which was similar to a 2D nanosheet.

In addition, the pyroelectric coefficient of the (Ba, Ca)TiO₃ thin film and the (Ca,Ba)TiO₃ thin film having A-site atomic layer gradient was measured to be about 2.55×10⁶ uC/m²K under the conditions of a temperature change period of 30 seconds and a temperature change of 7.5 K.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

100: perovskite oxide thin film
AL1, AL2, AL3, AL4: first to fourth atomic layers

What is claimed is:

1. A perovskite oxide thin film, comprising a compound represented by Chemical Formula 1, and having a layered perovskite structure,
wherein a ratio of A′ atoms to all A-sites in one A-site (A+A′) atomic layer is different from that of three or more other A-site atomic layers in a thickness direction:
A₁₋ₓA′ₓBO₃ [Chemical Formula 1]
wherein, in Chemical Formula 1,
A and A′ are different divalent or trivalent cations,
B is a tetravalent or trivalent cation, and
0≤x≤1.

2. The perovskite oxide thin film of claim 1, wherein
A and A′ are each independently strontium (Sr), calcium (Ca), barium (Ba), lanthanum (La), cerium (Ce), praseodymium (Pr), neodymium (Nd), promerium (Pm), samarium (Sm), europium (Eu), gadolinium (Gd), terbium (Tb), dysprosium (Dy), holmium (Ho), erbium (Er), thulium (Tm), ytterbium (Yb), lutepium (Lu), or a combination thereof, and
B is titanium (Ti), vanadium (V), chromium (Cr), manganese (Mn), iron (Fe), cobalt (Co), nickel (Ni), copper (Cu), zinc (Zn), or a combination thereof.

3. The perovskite oxide thin film of claim 1, wherein
the one A-site atomic layer is an A-site atomic layer (first atomic layer) disposed in a thickness direction of the perovskite oxide thin film, and
the three or more different A-site atomic layers include;
an A-site atomic layer (second atomic layer) that is disposed on a surface of the perovskite oxide thin film,
an A-site atomic layer (third atomic layer) that is disposed on an opposite surface of the perovskite oxide thin film, and
an A-site atomic layer (fourth atomic layer) that is disposed within the thickness direction of the perovskite oxide thin film and is different from the first atomic layer.

4. The perovskite oxide thin film of claim 3, wherein
ratios (R¹) of A′ atoms to all A-sites in the first atomic layer and the fourth atomic layer are each independently greater than 0 and less than about 1,
a ratio (R²) of A′ atoms to all A-sites in the second atomic layer is greater than 0 and less than about 1, and
a ratio (R³) of A′ atoms to all A-sites in the third atomic layer is greater than about 0 and less than or equal to about 1.

5. The perovskite oxide thin film of claim 3, wherein
the first atomic layer is an A-site atomic layer of the compound represented by Chemical Formula 1,
the second atomic layer is an A-site atomic layer of the compound represented by Chemical Formula 2,
the third atomic layer is an A-site atomic layer of the compound represented by Chemical Formula 3, and
the fourth atomic layer is an A-site atomic layer of the compound represented by Chemical Formula 4:
ABO₃ [Chemical Formula 2]
wherein, in Chemical Formula 2,
A is a divalent or trivalent cation different from A′, and
B is a tetravalent or trivalent cation,
A′BO₃ [Chemical Formula 3]
wherein, in Chemical Formula 3,
A′ is a divalent or trivalent cation different from A, and
B is a tetravalent or trivalent cation,
A_{1-z}A′_{z}BO₃ [Chemical Formula 4]
wherein, in Chemical Formula 4,
A and A′ are different divalent or trivalent cations,
B is a tetravalent or trivalent cation,
0<z<1, and
z≠x.

6. The perovskite oxide thin film of claim 5, wherein
the compound represented by Chemical Formula 1 is Ba₁₋ₓCaₓTiO₃,
the compound represented by Chemical Formula 2 is BaTiO₃,
the compound represented by Chemical Formula 3 is CaTiO₃, and
the compound represented by Chemical Formula 4 is Ba_{1-z}Ca_{z}TiO₃.

7. The perovskite oxide thin film of claim 1, wherein
the ratio of A′ atoms to all A-sites in one A-site atomic layer is a gradient change in the thickness direction of the perovskite oxide thin film.

8. The perovskite oxide thin film of claim 7, wherein
gradient change is calculated by Equation 1 is about 0.5% to about 50%:
$$Δ G ( \% ) = ( {AL}_{n + 1} - A {L}_{n} ) \times 100 \qquad [ Equation 1 ]$$
wherein, in Equation 1,
ΔG is a gradient in the thickness direction,
ALₙ is a ratio of A′ atoms to all A-sites in any one A-site atomic layer, and
ALₙ₊₁ is a ratio of A′ atoms to all A-sites in other A-site atomic layers separated by less than or equal to about 0.4 nm.

9. The perovskite oxide thin film of claim 1, wherein
a total thickness of the perovskite oxide thin film is about 1.2 nm to about 100 nm.

10. The perovskite oxide thin film of claim 1, wherein
an atomic ratio of A atoms to A′ atoms (A:A′) in the entire perovskite oxide thin film is about 30:70 to about 70:30.

11. The perovskite oxide thin film of claim 10, wherein
an average magnitude of polarization induced throughout the perovskite oxide thin film is greater than or equal to about 20 uC/cm².

12. The perovskite oxide thin film of claim 10, wherein
a dielectric loss throughout the perovskite oxide thin film is less than or equal to about 0.1 under measurement conditions of a frequency of 1 kHz to 2 MHz and an AC level of 10 mV to 200 mV.

13. The perovskite oxide thin film of claim 10, wherein
a pyroelectric coefficient of the entire perovskite oxide thin film is greater than or equal to about 10⁶ uC/m²K under measurement conditions of a temperature change period of 20 seconds to 120 seconds and a temperature change of 0.5 K to 8 K.

14. A method of preparing a perovskite oxide thin film, comprising
forming a perovskite oxide thin film that comprises a compound represented by Chemical Formula 1 and has a layered perovskite structure, on a substrate,
wherein a ratio of A′ atoms to all A-sites in one A-site (A+A′) atomic layer is different from that of three or more other A-site atomic layers in a thickness direction:
A₁₋ₓA′ₓBO₃ [Chemical Formula 1]
wherein, in Chemical Formula 1,
A and A′ are different divalent or trivalent cations,
B is a tetravalent or trivalent cation, and
0≤x<1.

15. The method of claim 14, wherein
the perovskite oxide thin film is formed by
a physical vapor deposition (PVD) method, a chemical vapor deposition (CVD) method, a molecular beam epitaxy (MBE) method, an atomic layer deposition (ALD) method, a pulsed laser deposition (PLD) method, or a sputter method.

16. The method of claim 14, wherein
the perovskite oxide thin film is formed using
PLD (Pulsed laser deposition) equipment equipped with a high-pressure-high-speed reflection electron diffraction device (reflection high energy electron diffraction), under certain conditions of a rate of 200 pulses/unit cell to 2 pulses/unit cell.
